(19) United States
(12) Patent Application Publication
(10) Pub. No.: US 2025/0147072 A1
(43) Pub. Date: May 8, 2025

(54) PROBE CARD, PROBE HEAD, METHOD FOR MANUFACTURING THE PROBE HEAD, AND ELECTRONIC DEVICE UNDER TEST TESTED BY THE PROBE CARD

(71) Applicant: MPI CORPORATION, Zhubei City (TW)

(72) Inventors: Chin-Tien YANG, Zhubei City (TW); Hui-Pin YANG, Zhubei City (TW)

(21) Appl. No.: 18/932,728

(22) Filed: Oct. 31, 2024

Related U.S. Application Data
(60) Provisional application No. 63/547,179, filed on Nov. 3, 2023.

(51) Int. Cl. G01R 1/073; G01R 1/067

(52) U.S. Cl. CPC G01R 1/07342; G01R 1/06716; G01R 1/06755; G01R 1/06772

(57) ABSTRACT

A probe card includes a circuit board, a space transformer, and a probe head. The probe head includes a probe pair, an insulating spacer, and a guide plate. Each probe in the probe pair includes a head portion, a tail portion, and a body portion located between the head portion and the tail portion and extending according to a longitudinal development axis. The body portion of each probe can deflect and deform on the longitudinal development axis when a load is applied to the probe. The guide plate includes a guide hole, and both probes of the probe pair pass through the guide hole. The hole diameter of the guide hole is larger than the hole diameter of the ground guide hole adjacent to the guide hole. The insulating spacer is coupled between the two probes, thereby maintaining the relative position between the two probes.

### CROSS-REFERENCE TO RELATED APPLICATIONS

This application claims priority to U.S. Provisional Application No. 63/547,179 filed on Nov. 3, 2023, the contents of which are incorporated herein by reference.

### BACKGROUND OF THE INVENTION

The present invention relates to a probe card, a probe head, and a method for manufacturing the probe head. More specifically, the present invention relates to a probe card, probe head, method for manufacturing the probe head, and an electronic device under test tested by the probe card, which can reduce the return loss between the probe card and the electronic device under test.

A probe card is an electrical testing tool used for testing semiconductor wafers or packaged devices. It generally includes at least a probe head, space transformer, and circuit board. The probe head may comprise multiple probes and multiple guide plates that secure the probes, typically including an upper guide plate and a lower guide plate. Each probe is placed in a guide hole of the upper guide plate and the lower guide plate. These guide holes ensure that the probes do not come into contact with each other due to excessive movement when they are in contact with the electronic device under test (DUT) integrated into the semiconductor wafer, thus allowing the probes to stably test the electrical performance of the DUT.

FIG. 1 illustrates a schematic view of the guide plate 1 in a traditional probe head from a top-down perspective. Referring to FIG. 1, the guide plate 1 may comprise guide holes 101 and 102, which may be arranged to accommodate probes 111 and 112, respectively. The probes 111 and 112 may be a pair of differential probes, meaning that these two probes may be configured to transmit a pair of differential signals to an electronic device under test. The probes 111 and 112 each leans on guide holes 101 and 102 in the rightward direction shown in the figure.

In recent years, the demand for high-frequency/high-speed testing of electronic devices under test has been increasing, and as the data transmission rate in testing rises (e.g., from 50-60 gigabits per second (Gbps) to over 100 Gbps), the impedance matching between the probe head and the electronic device under test has become increasingly significant for high-speed signal transmission. When there is impedance mismatch in the test path (i.e., the signal transmission path), the effect of return loss becomes significant. Therefore, how to effectively improve the impedance matching between the probe head and the electronic device under test to reduce the impact of return loss on the testing process is a highly focused issue in the technical field to which the present invention belongs.

### SUMMARY OF THE INVENTION

In order to at least solve the above-mentioned technical problem, reducing the effective dielectric constant between a pair of differential probes is a method that can theoretically improve the impedance matching between the probe head and the electronic device under test. Among the various methods to reduce the effective dielectric constant between two probes, the most intuitive and effective method is to reduce the distance between the probes in the differential pair. However, this approach is often limited by the spacing between the contact pads of the electronic device under test, making it impossible to adjust freely. However, after further review, the inventors of the present invention discovered that the effective dielectric constant between a pair of differential probes is greatly influenced by the material present between the two probes. Therefore, to reduce the effective dielectric constant, it is necessary to change the dielectric structure or contents between the two probes. The inventors of the present invention first attempted to dig through a pair of guide holes on the guide plate, which are configured to accommodate the differential probes, to form an enlarged guide hole. In this way, the dielectric between the two probes would only be air. However, in order to improve the electrical performance, if the two guide holes were dug through, the two probes would move excessively within the enlarged guide hole after being subjected to force during testing, and may even come into contact with each other.

FIG. 2 illustrates a schematic diagram of an enlarged guide hole formed by digging through the two guide holes in FIG. 1. Referring to FIG. 2, the originally separate guide holes 101 and 102 in FIG. 1 are dug toward each other to form an enlarged guide hole 21 in FIG. 2. Since probes 111 and 112 were originally supported by guide holes 101 and 102 in the rightward direction shown in the figure, during testing, probe 111 will inevitably move toward probe 112 within the dug guide hole 21 and come into contact with probe 112. This may cause a short circuit between the two probes, leading to damage such as probe burning or even the destruction of the entire probe card (circuit board). In light of this, how to reduce the effective dielectric constant between a pair of probes as much as possible in high-frequency testing while maintaining the relative position between the two probes to prevent contact with each other is a technical issue that must be resolved in the technical field to which the present invention belongs.

To at least solve the above technical problem, the present invention provides a probe head. The probe head may include a probe pair, a first insulating spacer, and a first guide plate. The two probes in the probe pair each include a head portion, a tail portion, and a body portion extending between the head portion and the tail portion along a longitudinal development axis. The body portion of each probe being able to arcuately deflect and deform along the longitudinal development axis when a load is applied to the respective probe The first guide plate may include a first enlarged guide hole, wherein the two probes of the probe pair both pass through the first enlarged guide hole, and an aperture of the first enlarged guide hole is larger than the aperture of a grounding guide hole adjacent to the first enlarged guide hole on the first guide plate. The first insulating spacer may be arranged between the two probes in the probe pair, thereby maintaining a relative position between the two probes.

To at least solve the above technical problem, the present invention further provides a probe card. The probe card may include a circuit board, a space transformer, and the probe head as described above. The space transformer may be positioned on the circuit board. The probe head may be arranged on the opposite side of the space transformer relative to the circuit board, and the tail portion of each probe in the probe pair of the probe head may be configured to electrically connect to the space transformer.

To at least solve the above technical problem, the present invention further provides a method for manufacturing a probe head, which may include the following steps:
placing, among a plurality of probes, the probes in pairs such that each pair is placed parallel to each other, thereby forming a plurality of probe pairs;
aligning, for each probe pair, two head portions and two tail portions of the two probes contained within the probe pair;
forming, for each probe pair, an insulating spacer between the two probes in the same probe pair, such that the insulating spacer is coupled with the two probes; and
passing the plurality of tail portions and a plurality of head portions of the plurality of probe pairs through an upper guide plate and a lower guide plate, thereby positioning the plurality of probe pairs between the upper guide plate and the lower guide plate, wherein:
   at least one of the upper guide plate or the lower guide plate contains a plurality of enlarged guide holes, each enlarged guide hole accommodating a part of the two probes contained in one of the probe pairs and at least a part of the insulating spacer between the two probes, and an aperture of each enlarged guide hole is larger than an aperture of a grounding guide hole adjacent to the same enlarged guide hole; and
   at least one of the upper guide plate and the lower guide plate also contains a plurality of non-enlarged guide holes, each non-enlarged guide hole accommodating a part of one of the probes, so that the head portion or tail portion of each probe pair that is not coupled by the insulating spacer therebetween passes through individually.

To at least solve the above technical problem, the present invention further provides an electronic device under test, which performs a high-frequency test procedure using a probe card associated with the above-described probe head. The high-frequency test procedure uses a high-frequency signal for testing, and the high-frequency test procedure is a feedback testing procedure.

In summary, the present invention provides a probe system and a probe card therein, wherein the probe head maintains the probe pitch (both center-to-center pitch and inner edge pitch) of each differential pair of probes through the insulating spacer. This allows the two guide holes on the guide plate originally corresponding to the differential pair probes to be dug through toward each other to form an enlarged guide hole, so that the effective dielectric constant between the two probes at the guide plate may be as close as possible to the effective dielectric constant of air while still ensuring that the two probes do not come into contact with each other during testing. This effectively solves the problem of the inability to maintain the probe pitch in the prior art due to the method of digging through the two guide holes to reduce the effective dielectric constant between the probes, and it combines the advantages of “improving the overall impedance matching between the probe head (or even the probe card to which it belongs) and the electronic device under test” and “increasing the positional stability of the probe pair during testing.” The more differential signal probe pairs to which the above mechanism provided by the present invention is applied, the greater the improvement effect.

The foregoing description provides a basic explanation of the present invention, including the technical problem solved by the present invention, the technical means employed, and the technical effects achieved. The following will further illustrate various embodiments of the present invention.

### BRIEF DESCRIPTION OF THE DRAWINGS

Shown as follows:

FIG. 1 illustrates the structure of a guide plate in the prior art from a top-down perspective.

FIG. 2 illustrates the structure of a guide plate from a top-down perspective according to one or more embodiments of the present invention.

FIG. 3 illustrates a wafer testing system where the probes, probe card, and probe head according to one or more embodiments of the present invention are located.

FIGS. 4-6 illustrate the structure of a guide plate and insulating spacer from a top-down perspective according to one or more embodiments of the present invention

FIG. 7 illustrates the cross-sectional structure of a probe device and probe holder from a side view according to one or more embodiments of the present invention.

FIG. 8 illustrates the structure of a probe according to one or more embodiments of the present invention.

FIG. 9 illustrates a flowchart of a method for manufacturing a probe head according to one or more embodiments of the present invention.

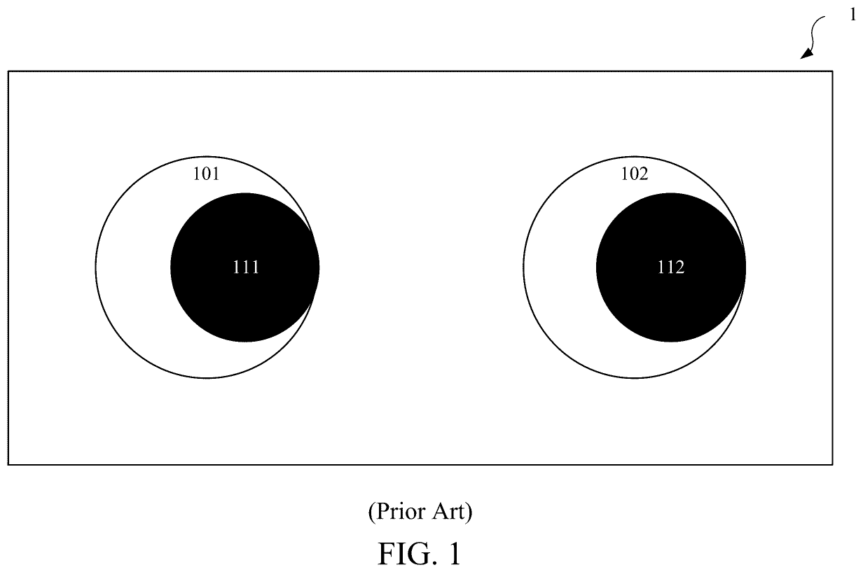

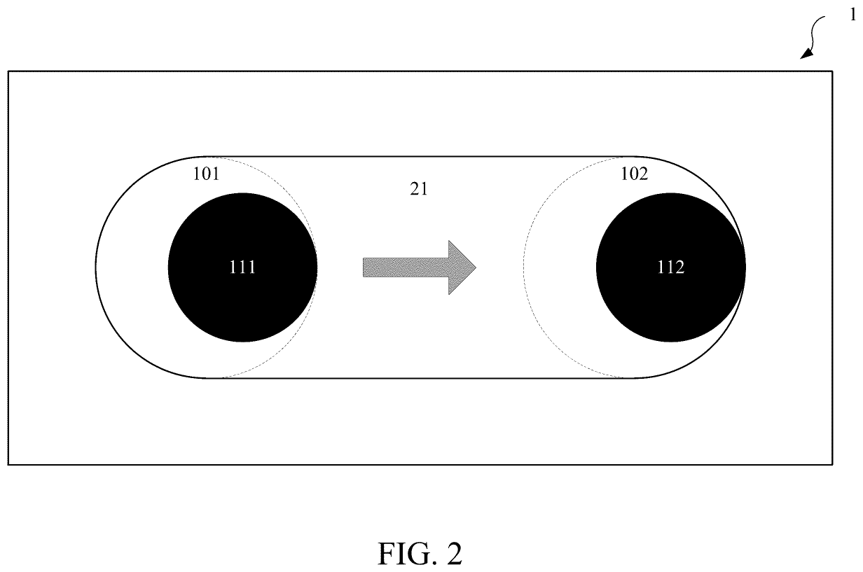

FIG. 2 to FIG. 9 are merely examples for illustrating the embodiments of the present invention and are not intended to limit the scope of protection of the present invention.

### DETAILED DESCRIPTION OF THE INVENTION

The following embodiments are not intended to limit the invention for which protection is sought to specific environments, applications, structures, processes, or situations. In the accompanying diagrams, components that are not directly related to the invention will be omitted. The sizes of the components and the size proportions between components in the accompanying diagrams are merely illustrative examples and are not intended to limit the invention. Unless specifically stated otherwise, identical component symbols in the following text may refer to the same components.

The terminology described herein is merely for ease of describing the embodiments and is not intended to limit the invention for which protection is sought. Unless explicitly stated otherwise, the term “a” before a component should be interpreted as “one type of” and includes both singular and plural forms. Terms such as “comprising,” “including,” and “having” are configured to specifically describe the existence of features, integers, steps, operations, components, ingredients, and/or groups that follow, but do not exclude the presence or addition of one or more other features, integers, steps, operations, components, ingredients, and/or groups. The term “and/or” is configured to indicate any combination of one or more of the related items listed. When terms such as “first,” “second,” and “third” are used to describe components, the purpose is not to limit the components described but to differentiate between them. Therefore, for example, without departing from the spirit or scope of the invention, the “first” component in order may also be referred to as the “second” component.

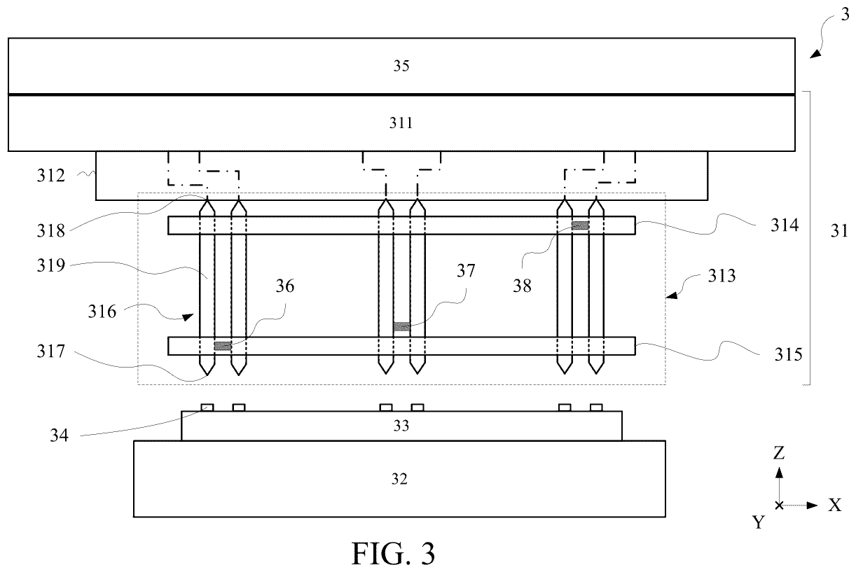

Referring to FIG. 3, it illustrates a probe system 3. The probe system 3 may include at least a probe card 31 and a chuck 32. The probe card 31 may be used for electrical connection and/or mechanical contact with the electronic device under test (DUT) 33 and for testing the electrical performance of the electronic device under test 33. The electronic device under test 33 may be a semiconductor wafer. The chuck 32 is configured to support the electronic device under test 33 for the probe card 31 to perform the testing. The electronic device under test 33 may include one or more contact pads (e.g., the contact pad 34 shown in FIG. 3), so that the probe tips are arranged to contact the one or more contact pads during the testing of the electronic device under test 33 (the probe tips shown in FIG. 3 have not yet made contact with the one or more contact pads).

The probe card 31 may include a circuit board 311, a space transformer 312, and a probe head 313. The space transformer 312 may be arranged on the circuit board 311, and the probe head 313 may be arranged on the space transformer 312. The probe head 313 basically includes a plurality of probes, an upper guide plate unit 314, and a lower guide plate unit 315. One end of each probe is electrically connected to the circuit board 311 through the space transformer 312, while the other end is designed to make contact with the contact pad (e.g., metal solder pad or conductive bump) on the electronic device under test 33 during testing. It should be noted that the space transformer 312 is described as being arranged on the circuit board 311 based on the conventional size relationship between the space transformer 312 and the circuit board 311, and this is not intended to limit the space transformer 312 to necessarily be positioned physically above the circuit board 311.

The testing equipment 35 may perform various testing procedures and/or communicate test information to the electronic device under test 33 through the probe card 31. The testing equipment 35, for example, may be a test head of a tester. In some embodiments, the testing procedures may include a loopback test, in which the electronic device under test 33 first generates the required high-frequency test signal. After passing through the probe card 31, the high-frequency test signal is then returned to the electronic device under test 33 for detection, thereby determining whether the electronic device under test 33 is functioning properly.

The circuit board 311 may include a wafer side and a tester side. The wafer side and the tester side of the circuit board 311 are positioned opposite each other, with the tester side being configured to connect to the testing equipment. In the embodiment shown in FIG. 3, the wafer side may be the lower surface of the circuit board 311, facing the space transformer 312 and/or the electronic device under test 33, while the tester side may be the upper surface of the circuit board 311, facing away from the electronic device under test 33 and/or towards the testing equipment 35. The circuit board 311 may be a standard printed circuit board (PCB), and it may have a top surface, a bottom surface, and a plurality of signal lines within it, with contact pads formed on the top and bottom surfaces that are electrically connected to the signal lines. The pogo pin of the testing equipment 35 may contact the contact pads on the top surface of the circuit board 311. The test signals from the testing equipment 35 are transmitted through the signal lines to the bottom surface of the circuit board 311.

The space transformer 312 may also include a wafer side and a tester side. The space transformer 312 may be composed of a multi-layer circuit board. The tester side of the space transformer 312 may be connected to the wafer side of the circuit board 311. In the embodiment shown in FIG. 3, the wafer side of the space transformer 312 may be the lower surface of the space transformer 312, which may face the probe head 313 and/or the electronic device under test 33, while the tester side of the space transformer 312 may be the upper surface of the space transformer 312, which may face away from the electronic device under test 33 and may face the circuit board 311 and/or the testing equipment 35. In this embodiment, the space transformer 312 may include a multilayer organic (MLO) substrate or a multilayer ceramic (MLC) substrate, with the material being adjustable according to actual needs; no specific limitations are made on the material in the present invention. The space transformer 312 contains a plurality of signal lines within it, and contact pads electrically connected to the internal signal lines are formed on the top and bottom surfaces, with the center spacing between the contact pads on the top surface being greater than the center spacing between the contact pads on the bottom surface. The space transformer 312 is mechanically and electrically connected to the wafer side of the circuit board 311, i.e., the bottom surface of the circuit board 311, and is positioned below the circuit board 311, so that the contact pads on the top surface of the space transformer 312 may be electrically connected to the contact pads on the bottom surface of the circuit board 311, thereby electrically connecting the internal signal lines of the space transformer 312 to the signal lines of the circuit board 311. However, in some embodiments, the space transformer 312 and the circuit board 311 may also be mechanically and/or electrically connected indirectly through another substrate (e.g., a spacer board), positioning the space transformer 312 on the wafer side of the circuit board 311.

The probe head 313 may be mechanically and/or electrically connected to the wafer side of the space transformer 312. As shown in FIG. 3, the probe head 313 may include an upper guide plate unit 314, a lower guide plate unit 315, and a plurality of probes (e.g., the probe 316 shown in FIG. 3). Each probe is configured to physically contact the electronic device under test 33. In some embodiments, the length of each probe may be no greater than 6 millimeters, and preferably no greater than 3 millimeters.

The upper guide plate unit 314 may include at least one upper guide plate, and the at least one upper guide plate may be equipped with a plurality of upper guide holes. The lower guide plate unit 315 may include at least one lower guide plate, and the at least one lower guide plate may be equipped with a plurality of lower guide holes. The upper guide plate unit 314 and the lower guide plate unit 315 may be positioned oppositely in the vertical direction along the longitudinal development axis (e.g., substantially along the coordinate axis Z of the local reference frame in FIG. 3, hereinafter referred to as the “Z-axis”). Each probe may pass through one of the plurality of upper guide holes and one of the plurality of lower guide holes. When the upper guide plate unit 314 is composed of a plurality of upper guide plates, there may be a gap between each upper guide plate in the direction corresponding to the longitudinal development axis. Similarly, when the lower guide plate unit 315 is composed of a plurality of lower guide plates, there may also be a gap between each lower guide plate in the direction corresponding to the longitudinal development axis (not shown in the figure), and this gap may be smaller than the gap between the upper guide plate unit 314 and the lower guide plate unit 315 in the direction corresponding to the longitudinal development axis.

The probes are typically made of special metals with excellent electrical and mechanical properties. By pressing the test head onto the electronic device under test 33, a good connection between each probe and the contact pads of the electronic device under test 33 may be ensured. During the pressing contact, the probes may slide within the guide holes on the upper and lower guide plates, and the probes may bend within the air gap 120 between the two guide plate units.

According to some embodiments of the present invention, each probe included in the probe head 313 may be a type of probe known in the field as a “buckling beam probe,” meaning that the probe body has a constant transverse cross-section (e.g., rectangular or trapezoidal, preferably square or rectangular) along its entire length, with the probe body having a deformed and flexible central portion that is suitable for bending. This allows the probe to further deform during the testing process of the electronic device under test 33. However, in some other embodiments, each probe does not necessarily have a constant transverse cross-section along its entire length.

The probes applicable to the present invention may include at least straight probes or pre-bent probes, among others. More specifically, straight probes may be, for example, forming wire (FW) probes or microelectromechanical system (MEMS) wire (i.e., MW) probes. Pre-bent probes may be, for example, cobra probes or microelectromechanical system (MEMS) probes with pre-bent probe bodies.

As shown in FIG. 3, each probe may include a head portion (e.g., the head portion 317 of the probe 316), a tail portion (e.g., the tail portion 318 of the probe 316), and a body portion (e.g., the body portion 319 of the probe 316) located between the head portion and the tail portion, extending along the longitudinal development axis. The head portion may end in a contact tip and may be configured to be adjacent to the contact pad of the electronic device under test 33, which is integrated within the semiconductor wafer. For example, as shown in FIG. 3, the head portion 117 is configured to be adjacent to the contact pad 34 of the electronic device under test 33. Each probe's body portion in the probe head 313 may bend or deflect arcuately along the longitudinal development axis when the probe is subjected to load (e.g., when the tip of each probe contacts the corresponding contact pad of the electronic device under test 33 during the testing process).

In some embodiments, the width of each probe's head portion may be greater than the width of the corresponding tail portion. The head portion of each probe may be enlarged by including an electroplating layer, such that the width of the head portion is greater than that of the tail portion (i.e., the head portion is thickened through electroplating). The thickness of the electroplating layer on the head portion may be, for example, between 5 microns and 20 microns, and preferably between 8 microns and 12 microns. Since the head portion needs to make contact with the guide holes of the lower guide plate unit 315 and the contact pads of the electronic device under test 33, the material of the electroplated layer may be wear-resistant metal. The thickening of the head portion may be done during manufacturing by thickening the contact area (e.g., by uniformly thickening the entire contact tip or by selectively thickening the part along the probe's central alignment direction). However, the thickening method is not limited to electroplating. For example, for microelectromechanical system (MEMS) probes, the contact area thickness may be increased through MEMS processing. When the contact area of each probe is thickened, the area of contact with the contact pad of the electronic device under test 33 is also increased, thereby providing a more stable contact method. In particular, when manufacturers reduce the center spacing between each probe pair to minimize return loss between the probe head 313 and the electronic device under test 33, the thickened contact area will still be able to make proper contact with the corresponding contact pad. The increase in thickness of the thickened contact area may range from 1 to 5 microns, and preferably from 1 to 2 microns. For example, in the case of a cobra probe, where the contact area is thickened by electroplating (i.e., increasing the diameter), when the thickness of the probe's head portion is 50 microns, a thickness of 1 to 2 microns may be formed on the corresponding contact area, resulting in a thickened contact area with a final thickness of 52 to 54 microns.

In some embodiments, in addition to widening/thickening the head portion, each probe in probe head 313 may have a body portion 319 that includes a flat structure, where the width of the flat structure is greater than the width of the corresponding probe's head portion. That is, the flattened probe body may be wider/thicker than the widened/thickened head portion. This flat structure indicates that the probe may undergo a flattening process during manufacturing. In some embodiments, the width of the body portion of each probe may range from 25 microns to 100 microns, and preferably from 55 microns to 65 microns.

Continuing with reference to FIG. 3, the tail portion 318 of each probe may pass through the guide hole on the upper guide plate unit 314 to electrically connect to the space transformer 312. The tail portion 318 may end at the contact tip and be configured to be adjacent to the contact pad of the space transformer 312 (not shown in the figure). The body portion 319 extends substantially along the longitudinal development axis between the head portion 317 and the tail portion 318.

The head portion 317 of each probe is used for electrical contact with the electronic device under test 33. More specifically, the head portion 317 of each probe may be configured to electrically communicate and/or physically contact the corresponding contact pad 34 of the electronic device under test 33. In some embodiments, this communication refers to the probe being configured to transmit test signals from the probe card 31 to the electronic device under test 33 and/or receive signals from the electronic device under test 33.

Various embodiments of the present invention relate to different configurations of the probe head 313. However, it should be noted that, although the probe structure in each embodiment of the present invention may differ slightly, the probe head in each embodiment generally includes at least one probe pair. In some embodiments, each probe pair is configured to transmit a set of differential signals, and such probe pairs may also be referred to as differential pairs. In the preferred embodiment of the present invention, the differential pair may use two single-ended signal lines (e.g., P-line and N-line) to connect TX+ and RX+, and TX− and RX−, respectively, to simultaneously transmit signals, with these two signals having the same voltage amplitude but opposite phases.

Between the two probes in each probe pair on the probe head 313, at least one insulating spacer may be provided, such as the insulating spacers 36 (as shown in FIG. 3, positioned in the enlarged guide hole of the lower guide plate unit 315 and coupled between the two head portions), insulating spacer 37 (positioned/coupled between the two body portions), and insulating spacer 38 (positioned in the enlarged guide hole of the upper guide plate unit 314 and coupled between the two tail portions). The insulating spacer is configured to maintain the distance between the two probes. As the name suggests, the insulating spacer may be made from insulating materials such as, but not limited to, reinforced plastics, plastic-steel, and other materials. In some embodiments, the material of the insulating spacer may be a porous filling material. In some embodiments, the material of the insulating spacer may have a relative dielectric constant not exceeding 6. In some embodiments, the material of the insulating spacer may even have a relative dielectric constant not exceeding 4. In some embodiments, the relative dielectric constant of the material of the insulating spacer may be no greater than the relative dielectric constants of the materials used in the upper guide plate unit 314 and the lower guide plate unit 315. In some embodiments, the width of the insulating spacer (in the direction corresponding to the X-axis of the local reference system shown in FIG. 3) may be smaller than the fine pitch (micro pitch) of the center of the two contact points on the electronic device under test 33 corresponding to the coupled probes.

In some embodiments, the insulating spacer may have a thickness corresponding to the longitudinal development axis, and this thickness may be less than or equal to the depth of the enlarged guide hole corresponding to the longitudinal development axis. That is, the insulating spacer may not protrude beyond the enlarged guide hole in the direction of the longitudinal development axis, such as insulating spacer 36 and insulating spacer 38 mentioned above.

In some embodiments, each probe pair, as a differential pair, on the probe head 313 may also have at least one ground probe corresponding thereto, and the probe spacing between the two probes in the differential pair (e.g., the center spacing of the body portion or the center spacing of the head portion) may be smaller than the distance between each of the two probes and the at least one ground probe (e.g., the center spacing of the body portion or the center spacing of the head portion). In other words, the two probes of the differential pair may be the probes that are closest to each other on the probe head 313.

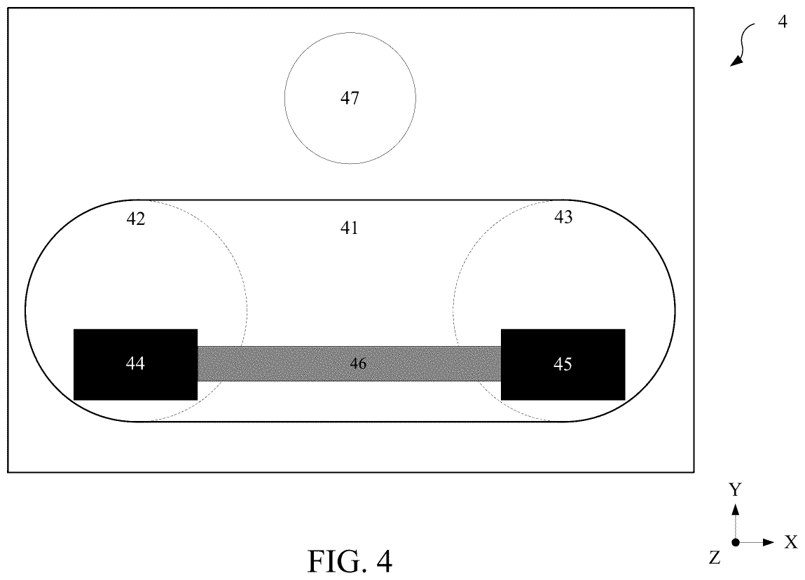

Next, referring to FIG. 4, which shows a partial view of the guide plate 4, the figure demonstrates a top-down perspective of possible implementations of the probe pair and insulating spacer in the upper guide plate unit 314 and/or the lower guide plate unit 315. In other words, the implementation shown in guide plate 4 in FIG. 4 may directly represent possible implementations of the upper guide plate unit 314 and the lower guide plate unit 315.

As shown in FIG. 4, the guide plate 4 may include a guide hole 41, which may be formed by punching through the original guide holes 42 and 43 (shown with dashed outlines in FIG. 4). The original guide holes 42 and 43 were configured to respectively accommodate probes 44 and 45 as a differential pair. In the scenario shown in FIG. 4, probes 44 and 45 are positioned to lean on guide holes 42 and 43 during testing, which are in the negative direction of the Y-axis of the local reference coordinate system (“Y-axis” in short). The bending direction of the body portions of the probes 44 and 45 during testing may be the positive direction of the Y-axis. In other words, the direction in which probes 44 and 45 lean on (rest against) guide holes 42 and 43, as well as the bending direction of the probes, are substantially perpendicular to the connection direction between the two probes.

In some embodiments, the diameter of the guide hole that was enlarged by punching through the original guide holes (referred to as an enlarged guide hole) may be larger than the diameters of other non-enlarged guide holes adjacent to the original guide holes on the guide plate. Examples of such other non-enlarged guide holes may include, but are not limited to, grounding guide holes arranged to accommodate a ground probe (also known as “G-probe”) or original guide holes arranged to accommodate one of the probes in another differential pair. For instance, in FIG. 4, the diameter of guide hole 41, which is the enlarged guide hole, is larger than the diameter of the corresponding grounding guide hole 47 for the probes 44 and 45 on the guide plate 4.

After the area between the two guide holes is punched through to form guide hole 41, even though probes 44 and 45 may not immediately slide toward each other (since the leaning direction is perpendicular to the direction of connection between the two probes), there is still a possibility that deformation and movement will occur due to the applied force during testing. Therefore, the relative distance between the probes 44 and 45, which was initially fixed, must be maintained by other means to prevent unnecessary movement or even accidental contact between the two probes during testing. As a result, an insulating spacer 46 may be placed between the probes 44 and 45 to couple them together and maintain their relative position, that is, to maintain the center spacing (pitch) between the probes. In some embodiments, the center distance between the probes 44 and 45 may range from 80 microns to 220 microns, with a preferred range of 100 microns to 130 microns.

The insulating spacer 46 may be placed between the head portions of the probes 44 and 45 or between the tail portions of the probes 44 and 45. When insulating spacer 46 is positioned between the head portions of the probes 44 and 45, the guide hole 41 may accommodate portions of the head portions of the probes 44 and 45 as well as at least part of insulating spacer 46. In other words, insulating spacer 46 may be partially or completely contained within the guide hole 41 of guide plate 4 along the longitudinal development axis (Z-axis).

The body portions of the probes 44 and 45 may have a transverse cross-section, as shown in FIG. 4, which is the transverse cross-section of the body portions of the probes 44 and 45. This transverse cross-section is taken by a plane perpendicular to the longitudinal development axis (e.g., parallel to the plane of guide plate 4). It should be noted that while FIG. 4 shows the transverse cross-section of the body portions of the two probes along with guide plate 4, this is merely for narrative convenience using the cross-section of the body portions and does not imply that the body portions of the two probes are actually leaning on (resting against) guide plate 4. The two probes lean on (rest against) guide plate 4 through their head portions or tail portions, depending on which component of the guide plate 4 is actually implemented as part of the upper guide plate unit 314 or lower guide plate unit 315.

As shown in FIG. 4, the body portions of the probes 44 and 45 may have a rectangular transverse cross-section, meaning the cross-section has a long side and a short side. In some embodiments, the insulating spacer 46 may be substantially aligned along the central connection direction of the head portions of the probes 44 and 45, coupling with each probe at the side of the short side of their respective head portions. Since the probes 44 and 45 lean on the long side of the transverse cross-section of their body portions as the deflection surface, and their bending direction is substantially perpendicular to the connection direction of the two probes, the probes are less likely to touch each other due to deformation from force during testing. Thus, compared to arranging the probes with the long side of the body portions aligned, arranging the probes with the short sides of the body portions aligned (as shown in FIG. 4) allows for a further reduction in the distance between the two probes (e.g., the inner edge distance of the body portions, or even the center-to-center distance), improving the overall electrical performance of the differential pair (when the two probes belong to the same differential pair). Additionally, because the distance between the two probes may be further reduced, the use of the insulating spacer 46 to maintain the distance between the probes becomes more critical in this field.

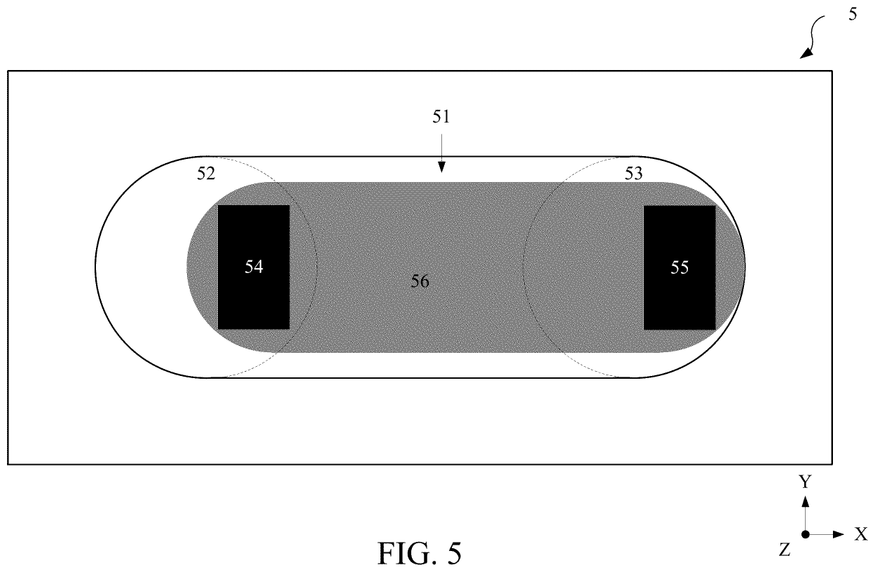

Referring to FIG. 5, which shows a partial view of a guide plate 5 from a top-down perspective, the probe pair and insulating spacer implementation in the upper guide plate unit 314 and/or lower guide plate unit 315 are illustrated. In other words, the guide plate 5 shown in FIG. 5 represents a potential implementation of the upper and lower guide plate units. As shown in FIG. 5, the guide plate 5 includes a guide hole 51, which is formed by expanding the original guide holes 52 and 53 (outlined in dashed lines in FIG. 5).

Similar to the situation with the guide holes 42 and 43, the guide holes 52 and 53 were originally arranged to accommodate the probes 54 and 55, respectively, as a differential pair. In the situation shown in FIG. 5, the probes 54 and 55 are arranged so that during testing, they lean on the guide holes 52 and 53 on the right side (the positive direction of the X-axis), with the bending direction of both probes being on the left side in FIG. 5. In other words, the direction of the probes leaning on the guide holes 52 and 53 and their bending direction are substantially parallel to the connection direction between the probes 54 and 55.

Since the leaning direction of the probes 54 and 55 is towards the right in FIG. 5, after the area between the guide holes 52 and 53 is expanded to form the guide hole 51, the probe 54 will slide towards the direction of the probe 55. Therefore, an insulating spacer 56 may be placed between the probes 54 and 55 to maintain their relative position, i.e., to maintain the spacing between the probes. In some embodiments, the center-to-center distance between the probes 54 and 55 may range from 80 microns to 220 microns, with an optimal range of 100 microns to 130 microns.

The difference between the insulating spacer 56 and the insulating spacer 46 is that the insulating spacer 56 not only provides support in the central connection direction of the two probes (i.e., the X-axis direction), but it also surrounds and covers the outer edges of the two probes, thus providing a more stable and comprehensive stabilizing effect. The outer edges refer to portions of the head portion, body portion, or tail portion of the probes, depending on the actual intersection of the insulating spacer with the probes. For example, the insulating spacer 56 may intersect with the probes 54 and 55 at the height of the guide plate 5 (e.g., relative to the longitudinal development axis/Z-axis), and insulating spacer 56 may surround and cover the probes 54 and 55 within the guide hole 51. In some embodiments, insulating spacer 56 may even completely fill the guide hole 51 in the X-axis and Y-axis directions (not shown). Additionally, in some embodiments, if the insulating spacer 56 is completely within the guide hole 51 along the longitudinal development axis/Z-axis direction, the insulating spacer 56 may also completely fill the guide hole 51 in the X, Y, and Z directions (not shown).

In some embodiments, the entire enlarged guide hole may be filled with material, and this material may serve as the insulating spacer between the two probes. The material may have a relative dielectric constant not greater than 6. In some embodiments, the material may even have a relative dielectric constant not greater than 4.

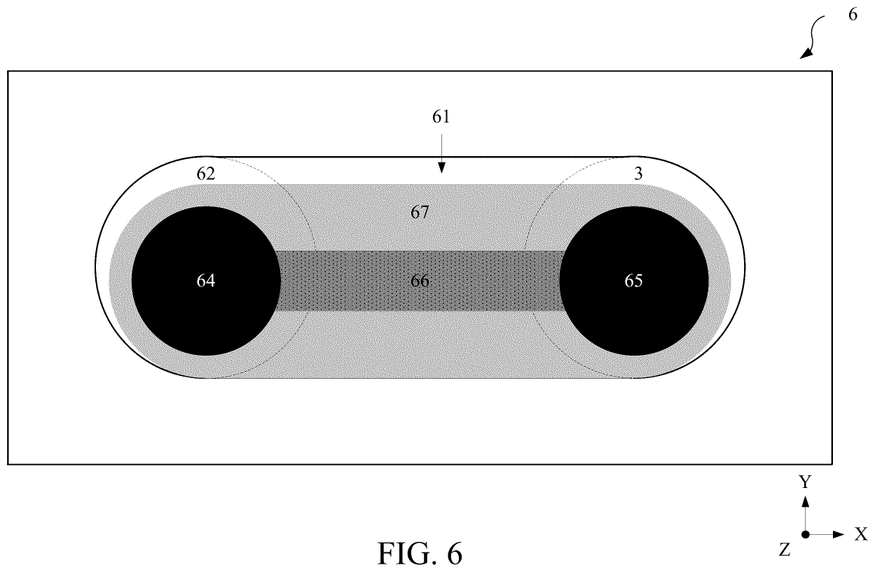

Referring to FIG. 6, which shows a partial view of a guide plate 6, a top-down perspective is configured to illustrate a possible implementation of the probe pair and insulating spacer in the upper guide plate unit 314 and/or lower guide plate unit 315. In other words, the implementation shown in the guide plate 6 may directly represent a possible configuration for upper guide plate unit 314 and lower guide plate unit 315. As shown in FIG. 6, guide plate 6 may include guide hole 61, which is formed by expanding the original guide holes 62 and 63 (represented by dashed lines in FIG. 6). Originally, the guide holes 62 and 63 could be arranged to accommodate the probes 64 and 65, which may be a differential pair. In the configuration shown in FIG. 6, the probes 64 and 65 are arranged to lean on the guide holes 62 and 63, respectively, in the negative direction of the Y-axis. The probes 64 and 65 are each located at the tail portion of the upper guide plate unit 314 and/or at the head portion of the lower guide plate unit 315, where they are shown to have substantially circular cross-sections. After the area between these two guide holes is expanded to form the guide hole 61, the probes 64 and 65, while not immediately sliding towards each other like the probes 54 and 55, will still experience deformation and movement during the testing process due to applied forces. Therefore, the originally fixed relative distance between the probes 64 and 65 must still be maintained by other means to prevent unnecessary movement during testing, and even potential contact between the two probes. Accordingly, an insulating spacer 66 may be placed between the probes 64 and 65 to maintain their relative position and the spacing between the probes.

Additionally, the insulating spacer 66 may be surrounded and covered at the guide hole 61 (e.g., at the same Z-axis height as the guide hole 61) by a reinforcement component 67. In some embodiments, the center spacing between the probes 64 and 65 may range from 80 microns to 220 microns, and preferably between 100 microns and 130 microns.

The reinforcement component 67 is arranged to enhance the deformation resistance of insulating spacer 66. In certain implementations, the reinforcement component 67 may also surround and cover both probes, similar to the insulating spacer 56 in the guide hole 61, providing a more stable and comprehensive support for the probes 64, 65, and the insulating spacer 66. This ensures that the probes 64 and 65 maintain their original alignment and relative distance in guide hole 61.

In some embodiments, the material of the reinforcement component 67 may be an insulating material, such as plastic, carbon fiber, or other non-metallic materials. However, in other implementations, the material of the reinforcement component 67 could be metallic, and in these cases, the inner edges of the reinforcement component 67 in contact with the probes 64, 65, and insulating spacer 66 may undergo insulation treatments (e.g., insulation coating, insulating varnish, etc.) to avoid affecting the electrical performance of the probes.

It should be noted that although in FIGS. 4, 5, and 6 the original guide holes before expansion are shown as circular, in some embodiments, the cross-sections of the guide holes may be substantially circular, elliptical, rectangular, or combinations of the aforementioned shapes.

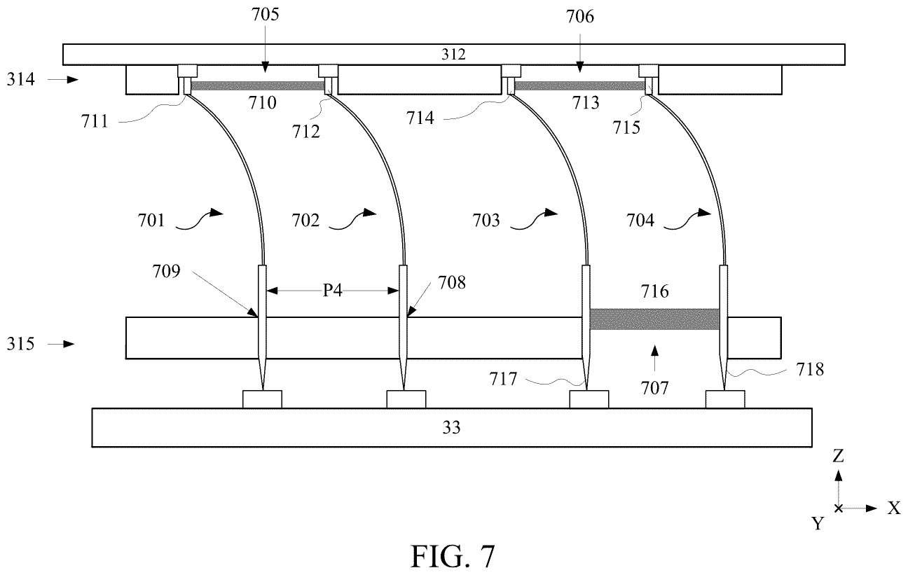

FIG. 7 illustrates, from a side view, an example of the arrangement of an insulating spacer and the enlarged guide hole within probe head 313 for a pre-bent type probe. Referring to FIG. 7, the probes 701 and 702, as one pair of differential probes, and the probes 703 and 704, as another pair of differential probes, all pass through upper guide plate unit 314 and lower guide plate unit 315. Each probe's head portion contacts a contact pad of the electronic device under test 33. Upper guide plate unit 314 may have guide holes 705 and 706, while lower guide plate unit 315 may have guide holes 707, 708, and 709. The guide holes 705, 706, and 707 in FIG. 7 are examples of “enlarged guide holes,” which are expanded from the original two standard guide holes into a single enlarged guide hole, similar to guide holes 41, 51, and 61 described earlier. For ease of explanation, the term “enlarged guide hole” will be configured to refer to this type of guide hole, while “standard guide hole” will refer to a non-enlarged guide hole.

It should be noted that, although the probes are shown in FIG. 7 in the form of pre-bent probes, this is not a direct limitation on the type of probes applicable to the present invention. In fact, the probes in FIG. 7 could also be replaced with straight probes.

The insulating spacer 710 may be positioned at guide hole 705 and coupled to the tail portions 711 and 712 of the probes 701 and 702, respectively. Similarly, the insulating spacer 713 may be positioned at guide hole 706 and coupled to the tail portions 714 and 715 of the probes 703 and 704, respectively. Another insulating spacer 716 may be positioned at guide hole 707 and coupled to the head portions 717 and 718 of the probes 703 and 704, respectively. Each insulating spacer may be coupled to the corresponding tail or head portions using methods such as adhesive bonding, embedding, or other means.

It should be noted that FIG. 7 illustrates various possible configurations of the upper guide plate unit 314, lower guide plate unit 315, and insulating spacers in a single diagram. This is not to imply that the actual implementation of the probe head 313 must strictly follow the configuration shown in FIG. 7. Instead, various mixed and matched configurations may be employed, as long as they can be successfully implemented.

In some embodiments, only one of the upper guide plate unit 314 or the lower guide plate unit 315 may contain an enlarged guide hole, while the other, which does not contain an enlarged guide hole, may include two standard guide holes (i.e., non-enlarged guide holes) through which the two probes of the probe pair pass. This situation corresponds to the result shown in the left half of FIG. 7, where the upper guide plate unit 314, the lower guide plate unit 315, the insulating spacer 710, and the probes 701 and 702 are depicted.

In some embodiments, the upper guide plate unit 314 and the lower guide plate unit may each include an enlarged guide hole, and the two probes of the probe pair pass through the enlarged guide holes in both the upper guide plate unit 314 and the lower guide plate unit. This situation corresponds to the result presented on the right side of FIG. 7, where the upper guide plate unit 314, the lower guide plate unit 315, the insulating spacers 713 and 716, and the probes 703 and 704 are shown. However, in some embodiments, an insulating spacer may be provided in only one enlarged guide hole, for example, only in the guide hole 707, while no insulating spacer is provided in guide hole 706. When both guide holes in the upper guide plate unit 314 and the lower guide plate unit 315 designed to accommodate a pair of probes are enlarged guide holes, but the insulating spacer is provided only in the enlarged guide hole of one guide plate, it is preferable to place the insulating spacer in the enlarged guide hole of the lower guide plate unit 315, which is closer to the electronic device under test 33.

In some embodiments, the insulating spacer may be fully located within the enlarged guide hole along the longitudinal development axis (i.e., the Z-axis shown in FIG. 7). A specific example of this scenario is insulating spacer 710 and insulating spacer 713, each being placed in the corresponding guide hole 705 and guide hole 706, respectively. Conversely, in some embodiments, the insulating spacer may only partially reside within the enlarged guide hole along the longitudinal development axis. A specific example of this scenario is insulating spacer 716, which is placed in the corresponding guide hole 707. Other examples include: insulating spacer 710 and/or insulating spacer 713 having part of it positioned lower than the lower surface of upper guide plate unit 314, insulating spacer 716 having part of it positioned lower than the lower surface of lower guide plate unit 315, and/or insulating spacer 716 having part of it positioned higher than the upper surface of lower guide plate unit 315.

In some embodiments, the insulating spacer 713 and insulating spacer 716 in FIG. 7 may even be replaced by a single insulating spacer, whose upper edge is located within the guide hole 706 and whose lower edge is located within the guide hole 707, and is coupled simultaneously to the tail portions 714 and 715 and the head portions 717 and 718 of the probes 703 and 704. This scenario may be considered as the insulating spacer 713 and insulating spacer 716 being vertically connected, although this configuration is not simultaneously presented in FIG. 7.

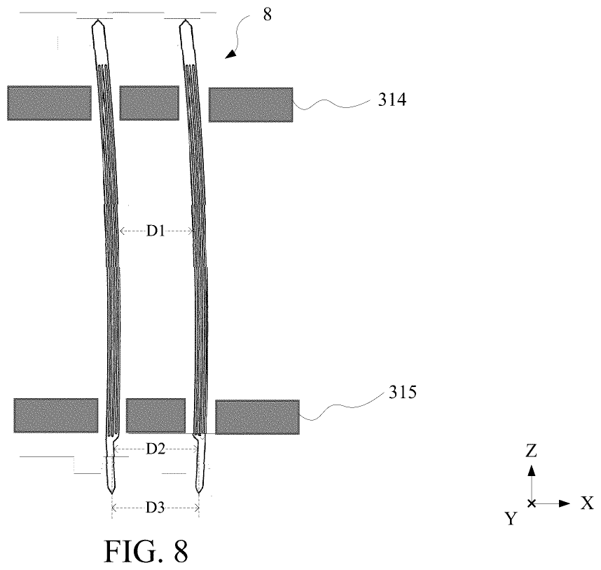

In some embodiments, the centerlines of the body portions of the two probes in each probe pair as part of a differential pair on the probe head 313 may be aligned without deviating from the centerline of their respective head portions. However, in some other embodiments, the centerlines of the body portions of the two probes in the differential pair may not align with the centerline of the head portion's contact area, resulting in a spacing between the centerlines of the body portions and the centerline of the contact area (i.e., the probe tip). This means that the spacing between the centerlines (may also be called as the center distance) of the body portions may differ from the spacing of the centerline (may also be called as the center distance) of the contact area on the head portion. Since the center distance of the contact areas of the two probes typically corresponds to the distance between the contact pads on the electronic device under test 33, and considering that the center distance of these contact pads (or the distance between any two contact points during testing) may not be a specification that the probe manufacturer can control, this arrangement allows the center distance of the body portions in the probe pair to be further reduced while keeping the center distance between the two contact areas fixed, thereby enhancing the electrical performance of the probe pair as a differential pair. A more specific example may be seen in FIG. 8, which illustrates an arrangement of the probe pairs on the probe head 313 using a probe pair 8 on the probe head 313 as an example. As shown in FIG. 8, the inner edge spacing D1 of the body portions of the two probes in probe pair 8 (e.g., as previously mentioned, the spacing between the probes 44 and 45 may be between 80 microns and 220 microns, and more preferably between 100 microns and 130 microns) may be smaller than the inner edge spacing D2 of the head portions of the two probes, or even smaller than the center distance D3 of the contact areas of the two contact points (e.g., contact pads) on the electronic device under test 33. The center distance D3 of the contact areas may be the same as the center distance of the head portions of the probe pair 8, ensuring accurate contact between the two.

In some embodiments, such as with pre-bent probes of the cobra type, the width formed by the two body portions of the two probes in each probe pair and the gap between these body portions may be larger than the width of the enlarged guide hole on the lower guide plate unit. This allows the two probes to press against the upper surface of the lower guide plate unit in the direction of the longitudinal development axis, preventing them from sliding downward further.

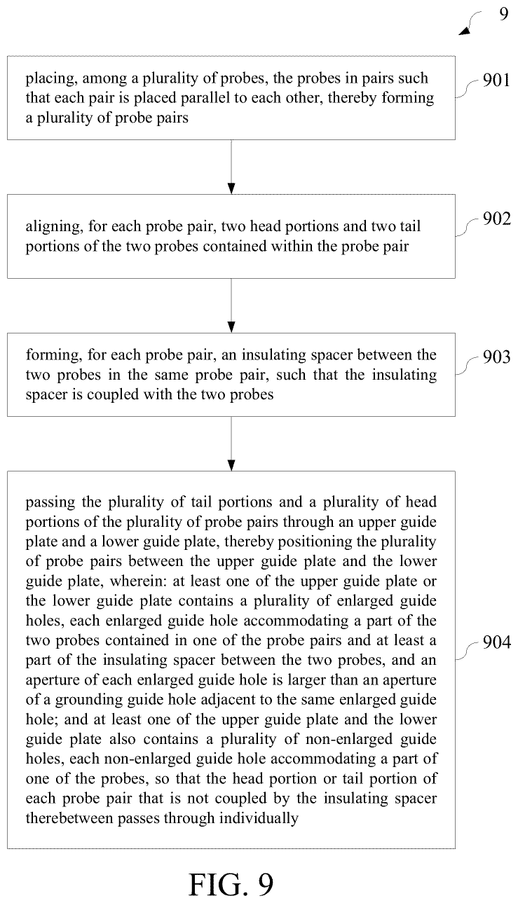

As shown in FIG. 9, embodiments of the present invention may also involve a probe head manufacturing method 9. The probe head manufacturing method 9 may include the following steps:
placing, among a plurality of probes, the probes in pairs such that each pair is placed parallel to each other, thereby forming a plurality of probe pairs (marked as 901);
aligning, for each probe pair, two head portions and two tail portions of the two probes contained within the probe pair (marked as 902);
forming, for each probe pair, an insulating spacer between the two probes in the same probe pair, such that the insulating spacer is coupled with the two probes (marked as 903);
passing the plurality of tail portions and a plurality of head portions of the plurality of probe pairs through an upper guide plate and a lower guide plate, thereby positioning the plurality of probe pairs between the upper guide plate and the lower guide plate, wherein: at least one of the upper guide plate or the lower guide plate contains a plurality of enlarged guide holes, each enlarged guide hole accommodating a part of the two probes contained in one of the probe pairs and at least a part of the insulating spacer between the two probes, and an aperture of each enlarged guide hole is larger than an aperture of a grounding guide hole adjacent to the same enlarged guide hole; and at least one of the upper guide plate and the lower guide plate also contains a plurality of non-enlarged guide holes, each non-enlarged guide hole accommodating a part of one of the probes, so that the head portion or tail portion of each probe pair that is not coupled by the insulating spacer therebetween passes through individually (marked as 904).

In some embodiments, regarding the probe head manufacturing method 9, the probes in the multiple probe pairs may all be pre-bent probes. The probe head manufacturing method 9 may further include the following steps: covering the lower guide plate first, allowing each of the plurality of head portions of the probe pairs to pass through one of the corresponding enlarged guide holes or one of the non-enlarged guide holes in the lower guide plate, then covering the upper guide plate, allowing each of the plurality of tail portions of the probe pairs to pass through one of the corresponding enlarged guide holes or one of the non-enlarged guide holes in the upper guide plate, thereby positioning the plurality of probe pairs between the upper guide plate and the lower guide plate.

In some embodiments, regarding the probe head manufacturing method 9, the probes in the multiple probe pairs may all be straight probes. The probe head manufacturing method 9 may further include the following steps: covering both the upper guide plate and the lower guide plate simultaneously, allowing each of the plurality of head portions of the probe pairs to pass through one of the corresponding enlarged guide holes or one of the non-enlarged guide holes in the lower guide plate, and making each of the plurality of tail portions of the probe pairs pass through one of the corresponding enlarged guide holes or one of the non-enlarged guide holes in the upper guide plate, thereby positioning the plurality of probe pairs between the upper guide plate and the lower guide plate.

Each embodiment of the probe head manufacturing method 9 basically corresponds to a specific embodiment of the probe head 313. Therefore, based on the previous description of the probe head 313, a person having ordinary skills in the art will be able to fully understand and implement all corresponding embodiments of the probe head manufacturing method 9, even if not every embodiment of the method has been elaborated in detail.

In summary, the present invention provides an insulating spacer for each probe pair in a probe card, ensuring the spacing between the two probes. This allows the original general guide holes in the upper guide plate and/or lower guide plate to be expanded into an enlarged guide hole. As a result, the effective dielectric constant between the two probes can be effectively reduced due to the contribution of the enlarged guide hole, which further improves the electrical performance of signal transmission when the probe pair is used as a differential pair. Accordingly, the probe card and the probe head provided by the present invention meet the electrical requirements for high-speed (high-frequency) testing, with enhanced signal integrity.

The above embodiments are provided merely to illustrate some of the embodiments of the present invention and explain the technical features of the present invention and are not intended to limit the scope of protection of the present invention. Any modifications or equivalent arrangements that can be easily made by a person having ordinary skills in the art are within the scope of the present invention, and the scope of protection claimed by the present invention is defined by the claims.

1. A probe head, comprising:
a probe pair, each of the two probes comprising a head portion, a tail portion, and a body portion extending between the head portion and the tail portion along a longitudinal development axis, the body portion of each probe being able to arcuately deflect and deform along the longitudinal development axis when a load is applied to the respective probe;
a first guide plate, comprising a first enlarged guide hole, wherein the two probes of the probe pair both pass through the first enlarged guide hole, and an aperture of the first enlarged guide hole is larger than the aperture of a grounding guide hole adjacent to the first enlarged guide hole on the first guide plate; and
a first insulating spacer, arranged between the two probes and coupled with the two probes, thereby maintaining a relative position between the two probes.

2. The probe head according to claim 1, wherein at least a part of the first insulating spacer is arranged within the first enlarged guide hole.

3. The probe head according to claim 1, further comprising a second guide plate, wherein:
the second guide plate is spaced a distance from the first guide plate along the longitudinal development axis; and
the second guide plate comprises two non-enlarged guide holes, and the two probes of the probe pair pass through the two non-enlarged guide holes, respectively.

4. The probe head according to claim 1, further comprising a second guide plate and a second insulating spacer, wherein:
the second guide plate is spaced a distance from the first guide plate along the longitudinal development axis;
the second guide plate comprises a second enlarged guide hole, and the two probes of the probe pair both pass through the first enlarged guide hole and the second enlarged guide hole;
the first guide plate is an upper guide plate, and at least a part of the tail portion of each of the two probes is arranged within the first enlarged guide hole;
the second guide plate is a lower guide plate, and at least a part of the head portion of each of the two probes is arranged within the second enlarged guide hole; and
the second insulating spacer is arranged between the two probes and coupled with the two probes, and at least a part of the second insulating spacer is arranged within the second enlarged guide hole.

5. The probe head according to claim 1, wherein:
the first insulating spacer is arranged between the two head portions of the two probes or between the two tail portions of the two probes;
the body portion of each of the two probes has a long side and a short side on a transverse cross-section of the body portion; and
the first insulating spacer is coupled with the two probes on a side corresponding to the short side of the head portion of each probe, or is coupled with the two probes on a side corresponding to the short side of the tail portion of each probe.

6. The probe head according to claim 4, wherein a width formed by the two body portions of the two probes and a gap between the two body portions outside the second enlarged guide hole is greater than a width of the second enlarged guide hole on the second guide plate, such that the two probes press against an upper surface of the second guide plate in a direction corresponding to the longitudinal development axis.

7. The probe head according to claim 1, wherein:
the first enlarged guide hole in the first guide plate has a depth corresponding to the longitudinal development axis; and
the first insulating spacer has a thickness corresponding to the longitudinal development axis, and the thickness of the first insulating spacer is less than or equal to the depth of the first enlarged guide hole.

8. The probe head according to claim 1, wherein a width of the first insulating spacer between the two probes is smaller than a center-to-center distance between the first enlarged guide hole and other guide hole adjacent to the first enlarged guide hole.

9. The probe head according to claim 1, wherein:
the first insulating spacer has a plurality of holes;
a relative dielectric constant of a material of the first insulating spacer is not greater than a relative dielectric constant of a material of the first guide plate; and
a cross-section of the first enlarged guide hole is circular, elliptical, rectangular, or a combination thereof.

10. The probe head according to claim 1, wherein the probe device further comprises at least one ground probe, and a distance between the two probes is less than a distance between each of the two probes and the at least one ground probe.

11. The probe head according to claim 1, wherein a width of the head portion of each of the two probes is greater than a width of the tail portion.

12. The probe head according to claim 1, wherein the two probes correspond to two contact points on an electronic device under test, and a distance between the head portions of the two probes is smaller than a center-to-center distance of the two contact points.

13. The probe head according to claim 11, wherein:
the head portion of each of the two probes comprises a plating layer, such that the width of the head portion of each of the two probes is greater than the width of the tail portion; and
the body portion of each of the two probes comprises a flat structure, and the width of the flat structure is greater than the width of the head portion of its respective probe.

14. The probe head according to claim 1, wherein:
the first enlarged guide hole is filled with a first material, and the first material has a relative dielectric constant not greater than 6; and
the first material has a relative dielectric constant not greater than 4.

15. The probe head according to claim 1, wherein the first insulating spacer surrounds and covers a part of each of the two probes of the probe pair.

16. The probe head according to claim 1, wherein the probe device further comprises a fastening member, the fastening member covering the first insulating spacer, and is configured to enhance the deformation resistance of the first insulating spacer.

17. The probe head according to claim 1, wherein a leaning direction of the probe pair with the first guide plate is substantially perpendicular to a direction of a line connecting the two probes of the probe pair.

18. A probe card, comprising:
a circuit board;
a space transformer, arranged on the circuit board; and
the probe head according to claim 1, being arranged on the opposite side of the space transformer relative to the circuit board, and the tail portion of each of the probes in the probe head is configured to be electrically connected to the space transformer.

19. An electronic device under test, wherein the electronic device under test undergoes a high-frequency testing procedure via the probe card according to claim 18, wherein the high-frequency testing procedure uses a high-frequency signal for testing, and the high-frequency testing procedure is a loopback testing procedure.

20. A method for manufacturing a probe head, comprising the following steps:
placing, among a plurality of probes, the probes in pairs such that each pair is placed parallel to each other, thereby forming a plurality of probe pairs;
aligning, for each probe pair, two head portions and two tail portions of the two probes contained within the probe pair;
forming, for each probe pair, an insulating spacer between the two probes in the same probe pair, such that the insulating spacer is coupled with the two probes; and
passing the plurality of tail portions and a plurality of head portions of the plurality of probe pairs through an upper guide plate and a lower guide plate, thereby positioning the plurality of probe pairs between the upper guide plate and the lower guide plate, wherein:
at least one of the upper guide plate or the lower guide plate contains a plurality of enlarged guide holes, each enlarged guide hole accommodating a part of the two probes contained in one of the probe pairs and at least a part of the insulating spacer between the two probes, and an aperture of each enlarged guide hole is larger than an aperture of a grounding guide hole adjacent to the same enlarged guide hole; and
at least one of the upper guide plate and the lower guide plate also contains a plurality of non-enlarged guide holes, each non-enlarged guide hole accommodating a part of one of the probes, so that the head portion or tail portion of each probe pair that is not coupled by the insulating spacer therebetween passes through individually.
